(19) United States
(12) Patent Application Publication
(10) Pub. No.: US 2026/0089854 A1
(43) Pub. Date: Mar. 26, 2026

(54) Power Module Having Features for Minimizing Baseplate Movement

(71) Applicant: Infineon Technologies AG, Neubiberg (DE)

(72) Inventors: Patrik Holt Jones, Soest (DE); Janine Pals, Erwitte (DE); Johannes Uhlig, Soest (DE)

(21) Appl. No.: 18/894,534

(22) Filed: Sep. 24, 2024

(51) Int. Cl. H05K 5/02

(52) U.S. Cl. CPC H05K 5/0217

(57) ABSTRACT

A power module includes a baseplate and an enclosure. The baseplate includes a first surface with a plurality of openings. The enclosure includes a first surface that faces the first surface of the baseplate and a plurality of posts jutting out from the first surface. Each of the posts of the enclosure is inserted into a respective opening of the baseplate. A first post of the enclosure is inserted into a first opening of the baseplate and is configured to minimize lateral movement of the baseplate relative to the enclosure. A second post of the enclosure is inserted into a second opening of the baseplate and is configured to minimize rotational movement of the baseplate about the first post.

### BACKGROUND

Demand for electronic modules for power applications, commonly referred to as power modules, continues to increase rapidly across a wide range of industries, including automotive, consumer electronics, renewable energy, manufacturing, and medical, among many others. Developments in semiconductor materials such as silicon carbide (SiC) and gallium nitride (GaN) have enabled such power modules to be manufactured with advantageous features such as smaller footprint, higher voltage and current capabilities, and faster switching speeds. Many applications have specific dimensional requirements for the power module (e.g., outer dimensions, alignment of features, etc.) In some instances, meeting these dimensional requirements necessitates tighter tolerances during the manufacturing of the power module, potentially increasing manufacturing complexity and/or cost.

Thus, there is a need for a solution that enables the power module to be manufactured to more relaxed tolerances while still meeting the dimensional requirements of applications that utilize the power module.

### SUMMARY

According to an embodiment of a power module, the power module comprises: a baseplate comprising a first surface with a plurality of openings; and an enclosure comprising a first surface that faces the first surface of the baseplate and a plurality of posts jutting out from the first surface, wherein each of the posts of the enclosure is inserted into a respective opening of the baseplate, wherein a first post of the enclosure is inserted into a first opening of the baseplate and is configured to minimize lateral movement of the baseplate relative to the enclosure, and wherein a second post of the enclosure is inserted into a second opening of the baseplate and is configured to minimize rotational movement of the baseplate about the first post.

According to an embodiment of a power module, the power module comprises: a baseplate comprising a first surface with a plurality of openings; and an enclosure comprising a first surface that faces the first surface of the baseplate and a plurality of posts jutting out from the first surface, wherein each of the posts of the enclosure is inserted into a respective opening of the baseplate, wherein a first post of the enclosure is inserted into a first opening of the baseplate, the first opening configured to minimize lateral movement of the baseplate relative to the enclosure, and wherein a second post of the enclosure is inserted into a second opening of the baseplate, the second opening configured to minimize rotational movement of the baseplate about the first post.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1A illustrates an exploded perspective view of a power module, according to an embodiment.

FIG. 1B illustrates a perspective view of a power module, according to an embodiment.

FIGS. 2A and 2B illustrate bottom plan views of a power module, according to embodiments.

FIGS. 3A-3C illustrate bottom plan views of a power module, according to embodiments.

### DETAILED DESCRIPTION

Described herein is a power module having an enclosure and a baseplate that are mated to one another by inserting posts of the enclosure into openings of the baseplate. Two of the posts and/or the respective openings into which they are inserted are designed with different dimensions, features, etc. than the other posts/openings, such that these two posts and/or their respective openings minimize movement of the baseplate relative to the enclosure. In this way, the alignment requirements between the enclosure and the baseplate for a given application of the power module may be met by designing only these posts and their respective openings to the tolerances that are needed to meet the alignment requirements, enabling the remainder of the posts and their respective openings to be designed to more relaxed tolerances and potentially providing a simpler, more cost-effective process for manufacturing the power module.

Described next, with reference to the figures, are exemplary embodiments of the power module having features configured to minimize movement of the baseplate relative to the enclosure.

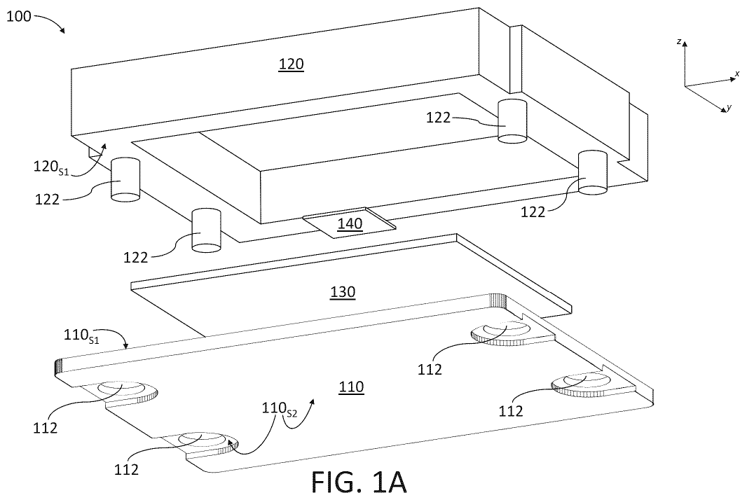

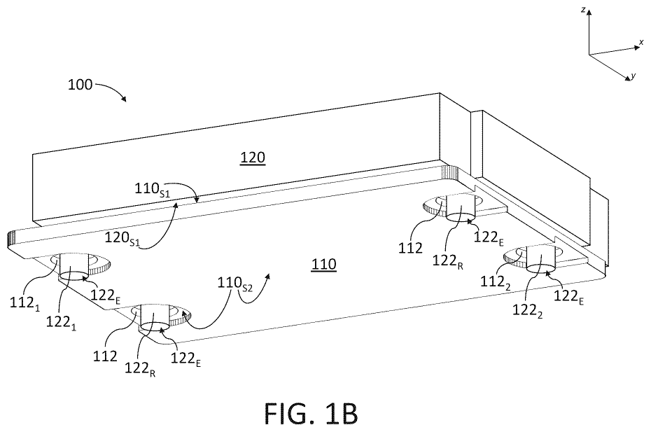

FIG. 1A illustrates an exploded perspective view of a power module 100, according to an embodiment. The power module 100 includes a baseplate 110, an enclosure 120, a substrate 130, and a power semiconductor die 140. The baseplate 110 includes a first surface 110_{S1} with a plurality of openings 112. In this example, each of the openings 112 extends through the baseplate 110 to a second surface 110_{S2} that is opposite the first surface 110_{S1}, although this is not a requirement. That is, one or more of the openings 112 may extend only partly through the baseplate 110. Each of the openings 112 is positioned in a recessed portion of the second surface 110_{S2}, although this too is not a requirement. The enclosure 120 includes a plurality of posts 122 jutting out from a first surface 120_{S1}. The first surface 120_{S1} of the enclosure faces the first surface 110_{S1} of the baseplate 110.

The baseplate 110 may be formed from any suitable material, e.g., a high thermal conductivity metal or metal alloy such as copper (Cu), aluminum (Al), AlCu, etc. to facilitate heat dissipation by the power module 100. Although not illustrated in FIG. 1A, the baseplate 110 may include protruding features (e.g., pins, fins, etc.) that are distributed over the second surface 110_{S2} and extend from the second surface 110_{S2}, e.g., in the −z direction of FIG. 1A. Such protruding features may enhance heat dissipation by the power module 100, e.g., by positioning them in a chamber of a cooling system that the power module 100 is mounted to.

The enclosure 120 may be a frame enclosure. A frame enclosure may include one or more pieces of metal, plastic, composite, and/or other suitable material that is structured and arranged (e.g., mated to the baseplate 110) to enclose the substrate 130 and the power semiconductor die 140. In some examples, the enclosure 120 is a molded enclosure that is formed from a mold compound. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc.

The posts 122 of the enclosure may be formed from the same material as the rest of the enclosure 120, or may be formed from a different material. For example, the posts 122 may be integrally formed with the rest of the enclosure 120. In another example, the posts 122 may be formed separately from the rest of the enclosure 120 and attached to the enclosure 120, inserted into openings in the enclosure 120, partly embedded in the enclosure 120, etc. In some examples, the posts 122 are configured to dissipate heat to the baseplate 110. Furthermore, although the posts 122 are illustrated herein as having a circular cylindrical shape, other shapes of the posts 122 are contemplated (e.g., square, rectangular, hexagonal, triangular, etc.)

Examples of the substrate 130 include a DCB (direct copper bonded) or AMB (active metal brazed) substrate, printed circuit board (PCB), lead frame, or other substrate, e.g., insulated metal substrate (IMS), etc. The substrate 130 may include one or more insulating layers and/or metallization layers. An insulating layer may include a ceramic, a polymer such as polyimide, etc. A metallization layer may include copper, aluminum, an alloy, etc., and may include one or more traces and/or contact pads. In some examples, a metallization layer may be configured to interface with another component (e.g., the baseplate 110).

The power semiconductor die 140 may include one or more devices, including transistors, diodes, resistors, capacitors, and/or other types of active or passive devices. In some examples, the power semiconductor die 140 is a vertical power semiconductor die (e.g., a vertical power transistor die). For a vertical power transistor die, the primary current flow path is between the front and back sides of the power semiconductor die 140 (along the z direction in FIG. 1A). In one embodiment, the power semiconductor die 140 is SiC transistor die such as a SiC power MOSFET (metal-oxide-semiconductor field-effect transistor) die. The power semiconductor die 140 may be a Si power MOSFET die, HEMT (high-electron mobility transistor) die, IGBT (insulated-gate bipolar transistor) die, JFET (junction filed-effect transistor) die, etc.

Although not specifically illustrated, the power module 100 may include one or more additional substrates 130 and/or additional power semiconductor dies 140. The substrates 130 may all be of a similar or identical design, or some or each of the substrates 130 may have different designs. Likewise, the power semiconductor dies 140 may all be of a similar or identical design (e.g., device type, structure, materials, dimensions, etc.), or some or each of the power semiconductor dies 140 may have different designs. Various arrangements and designs of the power semiconductor die(s) 140 and the substrate(s) 130 in the power module 100 are contemplated. The power semiconductor die(s) 140 and/or their constituent devices may be arranged to form all or part of a power electronics circuit such as a DC/AC inverter, a DC/DC converter, an AC/DC converter, an AC/AC converter, a multi-phase inverter, an H-bridge, motor driver, etc. In some examples, a power electronics circuit that includes the power semiconductor die(s) 140 is a half-bridge or full-bridge circuit.

FIG. 1B illustrates a perspective view of the power module 100, according to an embodiment. Specifically, FIG. 1B illustrates the power module 100 in an assembled state. The power module 100 may be assembled by attaching the power semiconductor die 130 to the substrate 140 (e.g., by soldering, diffusion soldering, brazing, adhering, etc.) and mating the enclosure 120 to the baseplate 110 such that the baseplate 110 and the enclosure 120 delimit an interior space of the power module 100 in which the power semiconductor die 130 and the substrate 140 are enclosed (not illustrated).

The enclosure 120 is mated to the baseplate 110 such that each of the posts 122 of the enclosure 120 is inserted into a respective opening 112 of the baseplate 110. A first post 122₁ of the enclosure 120 is inserted into a first opening 112₁ of the baseplate 110. A second post 122₂ of the enclosure 120 is inserted into a second opening 112₂ of the baseplate 110. A remainder of the posts 122_{R} comprises all of the plurality of posts 122 except the first post 122₁ and the second post 122₂. In this example, the remainder of the posts 122_{R} includes two posts 122_{R}, although any number of remaining posts 122_{R} is contemplated. Each post 122 of the enclosure 120 is inserted into a respective opening 112 such that the post 122 extends through the baseplate 110 and a distal end 122_{E} of the post 122 extends beyond the second surface 110_{S2} of the baseplate 110 (e.g., in the −z direction of FIG. 1B). In some examples, a volume of each of the first post 122₁, the second post 122₂, and each of the remainder of the posts 122_{R} is about the same.

According to an embodiment, the first post 122₁ and/or the first opening 112₁ are configured to minimize lateral movement of the baseplate 110 relative to the enclosure 120 (e.g., lateral movement in the x and/or y directions). According to an embodiment, the second post 122₂ and/or the second opening 112₂ are configured to minimize rotational movement of the baseplate 110 about the first post 122₁. As will be discussed, minimizing the lateral and rotational movement of the baseplate 110 relative to the enclosure 120 with the designs of the first and second posts 122₁ and 122₂ and/or the first and second openings 112₁ and 112₂ may provide a simpler, more cost-effective process for manufacturing the power module 100.

If the posts 122 are made of a deformable material, the enclosure 120 can be secured to the baseplate 110 by deforming the distal end 122_{E} of the posts 122. For example, if the posts 122 are made of a plastic material such as a mold compound material, the distal end 122_{E} of the posts 122 can be deformed by heating, pressure, ultrasonic welding, etc. The deformed distal end 122_{E} of the posts 122 has a wider lateral dimension than the baseplate opening 112, ensuring the posts 122 do not pull out from the openings 112.

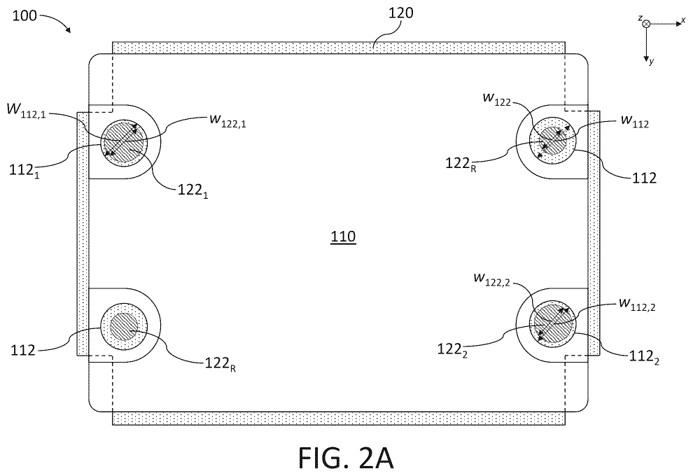

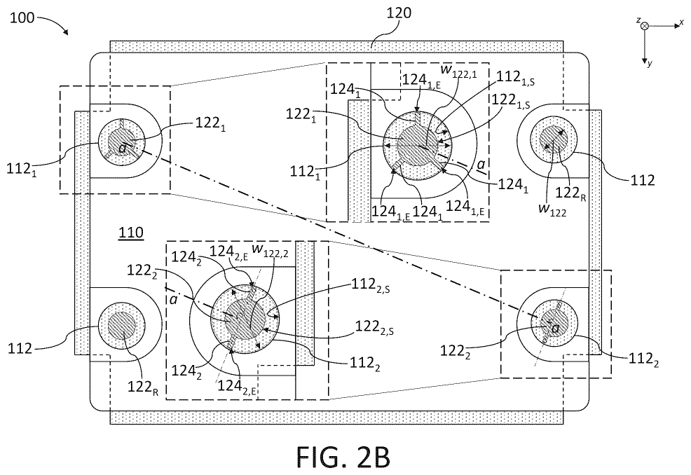

FIGS. 2A and 2B illustrate bottom plan views of the power module 100, according to embodiments. FIGS. 2A and 2B illustrate examples in which the first post 122₁ is configured to minimize lateral movement of the baseplate 110 relative to the enclosure 120 and the second post 122₂ is configured to minimize rotational movement of the baseplate 110 about the first post 122₁.

As illustrated in FIG. 2A, the first opening 112₁ has a width of w_{112,1}, and the second opening 112₂ has a width of w_{112,2}. The first post 122₁ has a width of w_{122,1}, and the second post 122₂ has a width of w_{122,2}. A post 122_{R} of the remainder of the posts 122_{R} has a width w₁₂₂ and is inserted into a respective opening 112 having a width of w₁₁₂. The width w_{122,1} of the first post 122₁ is greater than the width w₁₂₂ of the post 122_{R}. Likewise, the width w_{122,2} of the second post 122₂ is greater than the width w₁₂₂ of the post 122_{R}. When mating this configuration of the enclosure 120 with an example of the baseplate 110 in which the widths w_{112,1}, w_{112,2}, and w₁₁₂ of the openings 112₁, 112₂, and 112, respectively, are similar to one another, the result is a tighter tolerance between the first post 122₁ and the first opening 112₁ and between the second post 122₂ and the second opening 112₂ compared to the tolerance between the post 122_{R} having a width of w₁₂₂ and the respective opening 112 into which it is inserted. In examples in which the others of the remainder of the posts 122_{R} have similar or even larger tolerances with the respective openings 112 in which they are inserted, any movement of the baseplate 110 relative to the enclosure 120 (e.g., lateral and rotational movement in the x and or y directions) is minimized by the first post 122₁ and the second post 122₂. In this way, the alignment requirements between the enclosure 120 and the baseplate 110 may be met by designing only two of the posts 122, specifically the first post 122₁ and the second post 122₂, and their respective baseplate openings 112₁ and 112₂, to the required tolerances, enabling the remainder of the posts 122_{R} and their respective openings 112 to be designed to more relaxed tolerances and potentially providing a simpler, more cost-effective process for manufacturing the power module 100.

FIG. 2B illustrates an example of the power module 100 in which the first post 122₁ of the enclosure 120 comprises a first plurality of movement restriction features 124₁ and the second post 122₂ of the enclosure 120 comprises a second plurality of movement restriction features 124₂. Each of the first plurality of movements restriction features 124₁ extends from a surface 122_{1,S} of the first post 122₁ toward a surface 112_{1,S} that defines the first opening 112₁. In this example, each of the first plurality of movement restriction features 124₁ extends radially outward from the surface 122_{1,S} of the first post 122₁. Likewise, each of the second plurality of movement restriction features 124₂ extends from a surface 122_{2,S} of the second post 122₂, in this example radially outward from the surface 122_{2,S}, toward a surface 112_{2,S} that defines the second opening 112₂. Each of the movement restriction features of the first plurality 124₁ and the second plurality 124₂ may be a fin or other protrusion and may extend along part of or even the entire length of the respective post 122₁ and 122₂. While the second plurality of movement restriction features 124₂ illustrated has fewer movement restriction features than the first plurality of movement restriction features 124₁, this is only an example and is not a requirement.

As in the example of FIG. 2A, the movement of the baseplate 110 relative to the enclosure 120 in the example of FIG. 2B is minimized by the first post 122₁ and the second post 122₂. In this example, however, it is the movement restriction features 124₁ and 124₂ of the first post 122₁ and the second post 122₂, respectively, that minimize the movement of the baseplate 110 relative to the enclosure 120. Specifically, the width w_{122,1} of the first post 122₁, defined in this example by ends 124_{1,E} of the first plurality of movement restriction features 124₁, is greater than the width w₁₂₂ of the post 122_{R} of the remainder of the posts 122_{R}. The width w_{122,2} of the second post 122₂, defined in this example by ends 124_{2,E} of the second plurality of movement restriction features 124₂, is greater than the width w₁₂₂ of the post 122_{R} of the remainder of the posts 122_{R}. As in the example of FIG. 2A, when mating this configuration of the enclosure 120 with an example of the baseplate 110 in which the widths w_{112,1}, w_{112,2}, and w₁₁₂ of the openings 112₁, 112₂, and 112, respectively, are similar to one another, the result is a tighter tolerance between the first post 122 (specifically the first plurality of movement restriction features 124₁) and the first opening 112₁ and between the second post 122₂ (specifically the second plurality of movement restriction features 124₂) and the second opening 112₂ compared to the tolerance between the post 122_{R} having a width of w₁₂₂ and the respective opening 112 into which it is inserted. In examples in which the others of the remainder of the posts 122_{R} have similar tolerances with the respective openings 112 in which they are inserted, any movement of the baseplate 110 relative to the enclosure 120 is thus minimized by the first plurality of movement restriction features 124₁ of the first post 122₁ and the second plurality of movement restriction features 124₂ of the second post 122₂.

In the example of FIG. 2B, each of the second plurality of movement restriction features 124₂ is oriented substantially perpendicular to an axis a that extends between the first opening 112₁ and the second opening 112₂. Thus, as illustrated, first plurality of movement restriction features 124₁ of the first post 122₁ minimizes lateral movement of the baseplate 110 relative to the enclosure 120 (e.g., in the x and/or y directions), while the second plurality of movement restriction features 124₂ minimizes rotational movement of the baseplate 110 about the first post 122₁ due to their alignment perpendicular to the axis a.

In this way, the alignment requirements between the enclosure 120 and the baseplate 110 may be met by designing the dimensions, orientation, alignment, etc. of the movement restriction features 124₁ and 124₂ of the first post 122₁ and the second post 122₂, respectively, relative to their respective openings 112₁ and 112₂, enabling the remainder of the posts 122_{R} and their respective openings 112 to be designed to more relaxed tolerances and potentially providing a simpler, more cost-effective process for manufacturing the power module 100. Additionally, utilizing the movement restriction features 124₁ and 124₂ instead of simply making the first post 122₁ and the second post 122₂ wider may effectively relax the alignment tolerance between the enclosure 120 and the baseplate 110 since only parts of each of the first post 122₁ and the second post 122₂ (i.e., the first and second pluralities of movement restriction features 124₁ and 124₂) need to meet the required tolerances.

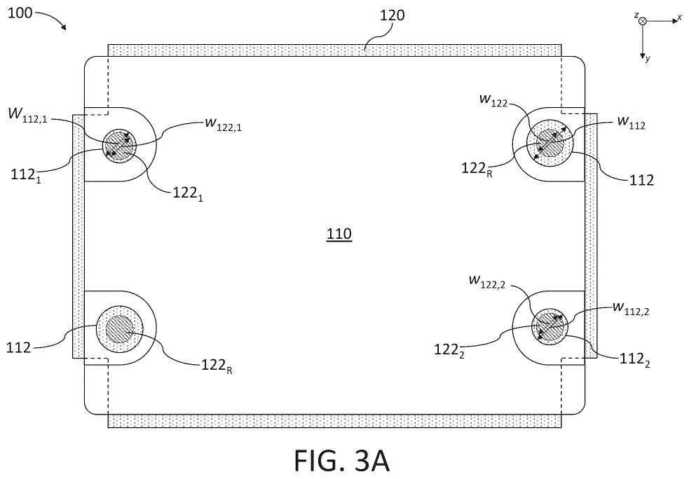

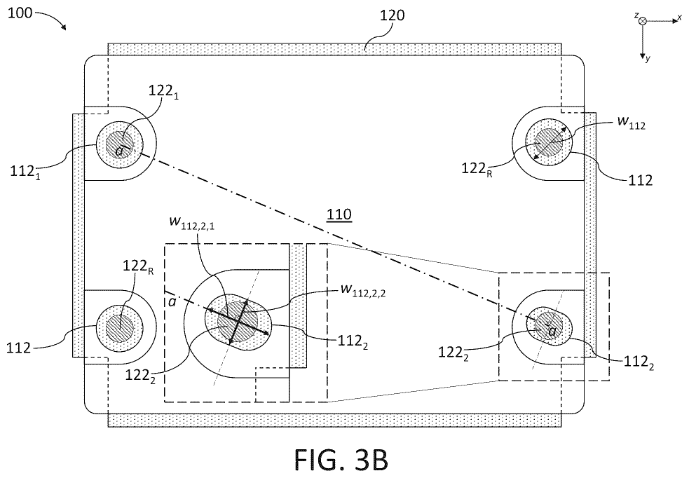

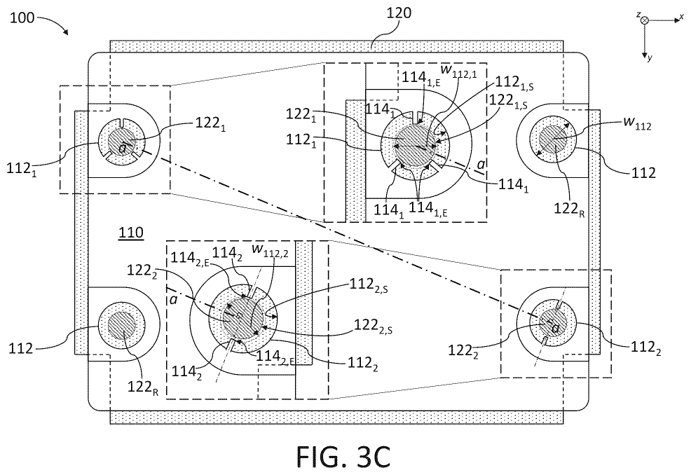

FIGS. 3A-3C illustrate bottom plan views of the power module 100, according to embodiments. FIGS. 3A-3C illustrate examples in which the first opening 112₁ is configured to minimize lateral movement of the baseplate 110 relative to the enclosure 120 and the second opening 112₂ is configured to minimize rotational movement of the baseplate 110 about the first post 122₁.

In the example of FIG. 3A, the width w_{112,1} of the first opening 112₁ and the width w_{112,2} of the second opening 112₂ are less than the width w₁₁₂ of the respective opening 112 into which the post 122_{R} of the remainder of the posts 122_{R} is inserted. When mating this configuration of the baseplate 110 with an example of the enclosure 120 in which the widths w_{122,1}, w_{122,2}, and w₁₂₂ of the first post 122₁, the second post 122₂, and the post 122_{R}, respectively, are similar to one another, the result is a tighter tolerance between the first post 122₁ and the first opening 112₁ and between the second post 122₂ and the second opening 112₂ compared to the tolerance between the post 122_{R} and the respective opening 112 into which it is inserted. In examples in which the others of the remainder of the posts 122_{R} have similar tolerances with the respective openings 112 in which they are inserted, any movement of the baseplate 110 relative to the enclosure 120 (e.g., lateral and rotational movement in the x and or y directions) is minimized by the first post 122₁ and the second post 122₂ due to the widths w_{112,1} and w_{112,2} of the first opening 112₁ and the second opening 112₂, respectively. In this way, the alignment requirements between the enclosure 120 and the baseplate 110 may be met by designing only two of the openings 112 of the baseplate 110, specifically the first opening 112₁ and the second opening 112₂, and their respective posts 122₁ and 122₂, to the required tolerances, enabling the remainder of the posts 122_{R} and their respective openings 112 to be designed to more relaxed tolerances and potentially providing a simpler, more cost-effective process for manufacturing the power module 100.

FIG. 3B illustrates an example in which the second opening 112₂ of the baseplate 110 has an elongated (e.g., elliptical) profile. Specifically, the second opening 112₂ of the baseplate 110 in FIG. 3B has a first width w_{112,2,1} that is parallel to the axis a that extends between the first opening 112₁ and the second opening 1122, and second width w_{112,2,2} perpendicular to the axis a, with the first width w_{112,2,1} greater than the second width w_{112,2,2}. Furthermore, the second width w_{112,2,2} of the second opening 112₂ is less than the width w₁₁₂ of the respective opening 112 into which the post 122_{R} of the remainder of the posts 122_{R} is inserted. When mating this configuration of the baseplate 110 with an example of the enclosure 120 in which the widths w_{122,2} and w₁₂₂ of the second post 112₂ and the post 112_{R}, respectively, are similar to one another, the second opening 112₂ minimizes rotational movement of the baseplate 110 about the first post 122₁ due its narrowed width w_{112,2,2} perpendicular to the axis a. Forming the second opening 1122 with this configuration may effectively relax the alignment tolerance between the enclosure 120 and the baseplate 110 compared to the example of the second opening 112₂ of FIG. 3A, since only one dimension of the second opening 112₂ has a tighter tolerance with the second post 122₂.

FIG. 3C illustrates an example of the power module 100 in which the first opening 112₁ of the baseplate 110 includes a first plurality of movement restriction features 114₁ and the second opening 112₂ of the baseplate 110 includes a second plurality of movement restriction features 114₂. Each of the first plurality of movement restriction features 114₁ extends from the surface 112_{1,S} that defines the first opening 112₁ of the baseplate toward the surface 122_{1,S} of the first post 122₁. Likewise, each of the second plurality of movement restriction features 114₂ extends from the surface 112_{2,S} that defines the second opening 112₂ of the baseplate 110 toward the surface 122_{2,S} of the second post 122₂. Each of the movement restriction features of the first plurality 114₁ and the second plurality 114₂ may be a fin or other protrusion and may extend along part of or even the entire length of the respective surface 112_{1,S} and 112_{2,S}. While the second plurality of movement restriction features 114₂ illustrated has fewer movement restriction features than the first plurality of movement restriction features 114₁, this is only an example and is not a requirement.

As in the example of the movement restriction features 124₁ and 124₂ of FIG. 2B, the movement of the baseplate 110 relative to the enclosure 120 in the example FIG. 3C is minimized by the movement restriction features 114₁ and 114₂. In this example, the width w_{112,1} of the first opening 112₁, defined by ends 114_{1,E} of the first plurality of movement restriction features 114₁, is less than the width w₁₁₂ of the opening 112 into which the post 122_{R} of the remainder of the posts 122_{R} is inserted. The width w_{112,2} of the second opening 112₂, defined by ends 114_{2,E} of the second plurality of movement restriction features 114₂, is less than the width w₁₁₂ of the opening 112 into which the post 122_{R} of the remainder of the posts 122_{R} is inserted. When mating this configuration of the baseplate 110 with an example of the enclosure 120 in which the widths w_{122,1}, w_{122,2}, and w₁₂₂ of the first post 122₁, the second post 122₂, and the post 122_{R}, respectively, are similar to one another, the result is a tighter tolerance between the first post 122₁ and the first opening 112₁ (specifically the first plurality of movement restriction features 114₁) and between the second post 122₂ and the second opening 112₂ (specifically the second plurality of movement restriction features 114₂) compared to the tolerance between the post 122_{R} and the respective opening 112 into which it is inserted. In examples in which the others of the remainder of the posts 122_{R} have similar tolerances with the respective openings 112 in which they are inserted, any movement of the baseplate 110 relative to the enclosure 120 is minimized by the first plurality of movement restriction features 114₁ of the first opening 112₁ and the second plurality of movement restriction features 114₂ of the second opening 112₂.

In the example of FIG. 3C, each of the second plurality of movement restriction features 114₂ of second opening 112₂ of the baseplate 110 is oriented substantially perpendicular to the axis a that extends between the first opening 112₁ and the second opening 112₂. Thus, as illustrated, the first plurality of movement restriction features 114₁ of the first opening 112₁ minimizes lateral movement of the baseplate 110 relative to the enclosure 120 (e.g., in the x and/or y directions), while the second plurality of movement restriction features 114₂ of the second opening 112₂ minimizes rotational movement of the baseplate 110 about the first post 122₁ due to their alignment perpendicular to the axis a.

In this way, the alignment requirements between the enclosure 120 and the baseplate 110 may be met by designing the dimensions, orientation, alignment, etc. of the movement restriction features 114₁ and 114₂ of the first opening 112₁ and the second opening 112₂, respectively, relative to their respective posts 122₁ and 122₂, enabling the remainder of the openings 112 and the posts 122_{R} to be designed to more relaxed tolerances and potentially providing a simpler, more cost-effective process for manufacturing the power module 100. Additionally, utilizing the movement restriction features 114₁ and 114₂ instead of simply making the first opening 112₁ and the second opening 112₂ narrower may effectively relax the alignment tolerance between the enclosure 120 and the baseplate 110 since only parts of each of the first opening 112₁ and the second opening 112₂ (i.e., the first and second pluralities of movement restriction features 114₁ and 114₂) need to meet the required tolerances.

Although the present disclosure is not so limited, the following numbered examples demonstrate one or more aspects of the disclosure.

Example 1. A power module, comprising: a baseplate comprising a first surface with a plurality of openings; and an enclosure comprising a first surface that faces the first surface of the baseplate and a plurality of posts jutting out from the first surface, wherein each of the posts of the enclosure is inserted into a respective opening of the baseplate, wherein a first post of the enclosure is inserted into a first opening of the baseplate and is configured to minimize lateral movement of the baseplate relative to the enclosure, and wherein a second post of the enclosure is inserted into a second opening of the baseplate and is configured to minimize rotational movement of the baseplate about the first post.

Example 2. The power module of example 1, wherein the first post of the enclosure comprises a first plurality of movement restriction features that each extends from a surface of the first post toward a surface that defines the first opening.

Example 3. The power module of example 2, wherein each of the first plurality of movement restriction features extends radially outward from the surface of the first post.

Example 4. The power module of any of examples 1 through 3, wherein the second post of the enclosure comprises a second plurality of movement restriction features that each extends from a surface of the second post toward a surface that defines the second opening, wherein each of the second plurality of movement restriction features is oriented substantially perpendicular to an axis that extends between the first opening and the second opening.

Example 5. The power module of example 4, wherein each of the second plurality of movement restriction features extends radially outward from the surface of the second post.

Example 6. The power module of any of examples 1 through 5, wherein the first post of the enclosure comprises a first plurality of movement restriction features that each extends from a surface of the first post toward a surface that defines the first opening, wherein the second post of the enclosure comprises a second plurality of movement restriction features that each extends from a surface of the second post toward a surface that defines the second opening, wherein each of the second plurality of movement restriction features is oriented substantially perpendicular to an axis that extends between the first opening and the second opening, and wherein the second plurality of movement restriction features has fewer movement restriction features than the first plurality of movement restriction features.

Example 7. The power module of any of examples 1 through 6, wherein a remainder of the posts comprises all of the plurality of posts except the first post and the second post, and wherein a width of the first post is greater than a width of at least one of the remainder of the posts.

Example 8. The power module of example 7, wherein the first post of the enclosure comprises a first plurality of movement restriction features that each extends from a surface of the first post toward a surface that defines the first opening, and wherein the width of the first post is defined by ends of the first plurality of movement restriction features.

Example 9. The power module of any of examples 1 through 8, wherein a remainder of the posts comprises all of the plurality of posts except the first post and the second post, and wherein a width of the second post is greater than a width of at least one of the remainder of the posts.

Example 10. The power module of example 9, wherein the second post of the enclosure comprises a second plurality of movement restriction features that each extends from a surface of the second post toward a surface that defines the second opening, wherein each of the second plurality of movement restriction features is oriented substantially perpendicular to an axis that extends between the first opening and the second opening, and wherein the width of the second post is defined by ends of the second plurality of movement restriction features.

Example 11. The power module of any of examples 1 through 10, wherein a remainder of the posts comprises all of the plurality of posts except the first post and the second post, and wherein a volume of each of the first post, the second post, and each of the remainder of the posts is about the same.

Example 12. The power module of any of examples 1 through 11, wherein at least one of the plurality of openings in the baseplate extends through the baseplate to a second surface of the baseplate that is opposite the first surface of the baseplate, wherein a respective post of the enclosure is inserted into a respective opening of the baseplate that extends through the baseplate such that the respective post extends through the baseplate and an end of the respective post extends beyond the second surface of the baseplate.

Example 13. A power module, comprising: a baseplate comprising a first surface with a plurality of openings; and an enclosure comprising a first surface that faces the first surface of the baseplate and a plurality of posts jutting out from the first surface, wherein each of the posts of the enclosure is inserted into a respective opening of the baseplate, wherein a first post of the enclosure is inserted into a first opening of the baseplate, the first opening configured to minimize lateral movement of the baseplate relative to the enclosure, and wherein a second post of the enclosure is inserted into a second opening of the baseplate, the second opening configured to minimize rotational movement of the baseplate about the first post.

Example 14. The power module of any of examples 1 through 13, wherein a remainder of the posts comprises all of the plurality of posts except the first post and the second post, and wherein a width of the first opening is less than a width of at least one opening into which a respective post of the remainder of the posts is inserted.

Example 15. The power module of example 14, wherein the first opening of the baseplate comprises a first plurality of movement restriction features that each extends from a surface that defines the first opening toward a surface of the first post, and wherein the width of the first opening is defined by ends of the first plurality of movement restriction features.

Example 16. The power module of any of examples 1 through 15, wherein a remainder of the posts comprises all of the plurality of posts except the first post and the second post, and wherein a width of the second opening is less than a width of at least one opening into which a respective post of the remainder of the posts is inserted.

Example 17. The power module of example 16, wherein the second opening of the baseplate comprises a second plurality of movement restriction features that each extends from a surface that defines the second opening toward a surface of the second post, wherein each of the second plurality of movement restriction features is oriented substantially perpendicular to an axis that extends between the first opening and the second opening, and wherein the width of the second opening is defined by ends of the second plurality of movement restriction features.

Example 18. The power module of any of examples 1 through 17, wherein the second opening has a first width that is parallel to an axis that extends between the first opening and the second opening, wherein the first width is greater than a second width of the second opening, the second width perpendicular to the axis that extends between the first opening and the second opening.

Example 19. The power module of example 18, wherein a remainder of the posts comprises all of the plurality of posts except the first post and the second post, and wherein the second width of the second opening is less than a width of at least one opening into which a respective post of the remainder of the posts is inserted.

Example 20. The power module of any of examples 1 through 19, wherein at least one of the plurality of openings in the baseplate extends through the baseplate to a second surface of the baseplate that is opposite the first surface of the baseplate, wherein a respective post of the enclosure is inserted into a respective opening of the baseplate that extends through the baseplate such the respective post extends through the baseplate and an end of the respective post extends beyond the second surface of the baseplate.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power module, comprising:
a baseplate comprising a first surface with a plurality of openings; and
an enclosure comprising a first surface that faces the first surface of the baseplate and a plurality of posts jutting out from the first surface, wherein each of the posts of the enclosure is inserted into a respective opening of the baseplate,
wherein a first post of the enclosure is inserted into a first opening of the baseplate and is configured to minimize lateral movement of the baseplate relative to the enclosure, and
wherein a second post of the enclosure is inserted into a second opening of the baseplate and is configured to minimize rotational movement of the baseplate about the first post.

2. The power module of claim 1, wherein the first post of the enclosure comprises a first plurality of movement restriction features that each extends from a surface of the first post toward a surface that defines the first opening.

3. The power module of claim 2, wherein each of the first plurality of movement restriction features extends radially outward from the surface of the first post.

4. The power module of claim 1, wherein the second post of the enclosure comprises a second plurality of movement restriction features that each extends from a surface of the second post toward a surface that defines the second opening, wherein each of the second plurality of movement restriction features is oriented substantially perpendicular to an axis that extends between the first opening and the second opening.

5. The power module of claim 4, wherein each of the second plurality of movement restriction features extends radially outward from the surface of the second post.

6. The power module of claim 1,
wherein the first post of the enclosure comprises a first plurality of movement restriction features that each extends from a surface of the first post toward a surface that defines the first opening,
wherein the second post of the enclosure comprises a second plurality of movement restriction features that each extends from a surface of the second post toward a surface that defines the second opening, wherein each of the second plurality of movement restriction features is oriented substantially perpendicular to an axis that extends between the first opening and the second opening, and
wherein the second plurality of movement restriction features has fewer movement restriction features than the first plurality of movement restriction features.

7. The power module of claim 1,
wherein a remainder of the posts comprises all of the plurality of posts except the first post and the second post, and
wherein a width of the first post is greater than a width of at least one of the remainder of the posts.

8. The power module of claim 7,
wherein the first post of the enclosure comprises a first plurality of movement restriction features that each extends from a surface of the first post toward a surface that defines the first opening, and
wherein the width of the first post is defined by ends of the first plurality of movement restriction features.

9. The power module of claim 1,
wherein a remainder of the posts comprises all of the plurality of posts except the first post and the second post, and
wherein a width of the second post is greater than a width of at least one of the remainder of the posts.

10. The power module of claim 9,
wherein the second post of the enclosure comprises a second plurality of movement restriction features that each extends from a surface of the second post toward a surface that defines the second opening, wherein each of the second plurality of movement restriction features is oriented substantially perpendicular to an axis that extends between the first opening and the second opening, and
wherein the width of the second post is defined by ends of the second plurality of movement restriction features.

11. The power module of claim 1,
wherein a remainder of the posts comprises all of the plurality of posts except the first post and the second post, and
wherein a volume of each of the first post, the second post, and each of the remainder of the posts is about the same.

12. The power module of claim 1,
wherein at least one of the plurality of openings in the baseplate extends through the baseplate to a second surface of the baseplate that is opposite the first surface of the baseplate,
wherein a respective post of the enclosure is inserted into a respective opening of the baseplate that extends through the baseplate such that the respective post extends through the baseplate and an end of the respective post extends beyond the second surface of the baseplate.

13. A power module, comprising:
a baseplate comprising a first surface with a plurality of openings; and
an enclosure comprising a first surface that faces the first surface of the baseplate and a plurality of posts jutting out from the first surface, wherein each of the posts of the enclosure is inserted into a respective opening of the baseplate,
wherein a first post of the enclosure is inserted into a first opening of the baseplate, the first opening configured to minimize lateral movement of the baseplate relative to the enclosure, and
wherein a second post of the enclosure is inserted into a second opening of the baseplate, the second opening configured to minimize rotational movement of the baseplate about the first post.

14. The power module of claim 13,
wherein a remainder of the posts comprises all of the plurality of posts except the first post and the second post, and
wherein a width of the first opening is less than a width of at least one opening into which a respective post of the remainder of the posts is inserted.

15. The power module of claim 14,
wherein the first opening of the baseplate comprises a first plurality of movement restriction features that each extends from a surface that defines the first opening toward a surface of the first post, and
wherein the width of the first opening is defined by ends of the first plurality of movement restriction features.

16. The power module of claim 13,
wherein a remainder of the posts comprises all of the plurality of posts except the first post and the second post, and
wherein a width of the second opening is less than a width of at least one opening into which a respective post of the remainder of the posts is inserted.

17. The power module of claim 16,
wherein the second opening of the baseplate comprises a second plurality of movement restriction features that each extends from a surface that defines the second opening toward a surface of the second post, wherein each of the second plurality of movement restriction features is oriented substantially perpendicular to an axis that extends between the first opening and the second opening, and
wherein the width of the second opening is defined by ends of the second plurality of movement restriction features.

18. The power module of claim 13,
wherein the second opening has a first width that is parallel to an axis that extends between the first opening and the second opening,
wherein the first width is greater than a second width of the second opening, the second width perpendicular to the axis that extends between the first opening and the second opening.

19. The power module of claim 18,
wherein a remainder of the posts comprises all of the plurality of posts except the first post and the second post, and
wherein the second width of the second opening is less than a width of at least one opening into which a respective post of the remainder of the posts is inserted.

20. The power module of claim 13,
wherein at least one of the plurality of openings in the baseplate extends through the baseplate to a second surface of the baseplate that is opposite the first surface of the baseplate,
wherein a respective post of the enclosure is inserted into a respective opening of the baseplate that extends through the baseplate such the respective post extends through the baseplate and an end of the respective post extends beyond the second surface of the baseplate.
